(19) United States
(12) Patent Application Publication
(10) Pub. No.: US 2013/0241578 A1
(43) Pub. Date: Sep. 19, 2013

(54) CAPACITANCE TYPE SENSOR

(71) Applicant: DENSO CORPORATION, Kariya-city (JP)

(72) Inventors: Masayoshi Satake, Okazaki-city (JP); Hiroyuki Mori, Obu-city (JP); Hajime Nakagawa, Nagoya-city (JP)

(73) Assignee: DENSO CORPORATION, Kariya-city (JP)

(21) Appl. No.: 13/792,987

(22) Filed: Mar. 11, 2013

(30) Foreign Application Priority Data
Mar. 15, 2012 (JP) 2012-058942

(51) Int. Cl. G01R 27/26

(52) U.S. Cl. CPC G01R 27/2605
USPC 324/661

(57) ABSTRACT

A capacitance type sensor includes a detection electrode, a reference electrode, and a sub-reference electrode for distinguishingly detecting a detection object. The sub-reference electrode has a reference voltage applied thereto and is displaceable relative to the detection electrode due to a pressure exerted from the detection object. A voltage application device applies a detection voltage to form an electric field in a space defined with the reference electrode device. A capacitance detector of the sensor detects a first capacitance and a second capacitance, and a detection unit of the sensor distinguishingly detects the detection object based on the first capacitance and the second capacitance. The first capacitance is measured between the detection electrode and the reference electrode, and the second capacitance is measured between the detection electrode and the sub-reference electrode.

### CROSS REFERENCE TO RELATED APPLICATION

This application is based on and claims the benefit of priority of Japanese Patent Application No. 2012-58942 filed on Mar. 15, 2012, the disclosure of which is incorporated herein by reference.

### TECHNICAL FIELD

The present disclosure generally relates to a capacitance type sensor for distinctively detecting a detection object based on capacitance.

### BACKGROUND

The capacitance type sensor is a device that detects and distinguishes a detection object, in terms of the presence of the detection object and the type of the detection object, based on a change of the capacitance between two electrodes. The capacitance type sensor may be used, for example, as a touch panel or an occupant detection sensor. An example of a capacitance type occupant detection sensor is disclosed in Japanese Patent Laid-Open No. 2008-111809 (i.e., a patent document 1). The capacitance type occupant detection sensor has one electrode disposed in a seat of a vehicle, and detects, based on the change of the capacitance, whether an occupant is sitting on the seat or not, or what kind of occupant (i.e., an adult, a child in a child restraint system (CRS), or the like) is sitting on the seat. More practically, the difference between the relative dielectric constants of the detection objects (e.g., air=1, CRS=2 to 5, adult≅50), which causes the change of the detected capacitance, enables the distinctive detection of the object on the seat.

However, when a thick object other than a human body exists between the detection object and a contact surface (i.e., a seat surface, a screen of a touch panel or the like) or between the detection object and a detection electrode, the change of the capacitance by the detection object is made smaller, thereby deteriorating a detection accuracy of the capacitance type sensor.

For instance, when an occupant is wearing thick clothes, or when a cushion is put on a seat surface, the occupant detection sensor may have an increase in the capacitance that is less than an expected amount of increase. Further, when a CRS having a child sitting therein is put on the seat, a conductor of the CRS or other nearby object may form an electric field (i.e., capacitance) with the electrode of the occupant detection sensor, making the increase of the capacitance greater than expected. As a result, the smaller-than-expected capacitance of the adult and the greater-than-expected capacitance of the CRS-accommodated child may be a small difference, and may make it difficult to distinguish between an adult and a child in CRS, and may deteriorate the distinction accuracy.

Further, when the touch panel is used as an interface, the touch on the touch panel screen with the user's hand covered by a glove or the like may make only a small increase of the capacitance, thereby disabling the detection of the user's touch on the touch screen.

### SUMMARY

In an aspect of the present disclosure, a capacitance type sensor may include: a detection electrode arranged to face a detection object, a reference electrode provided with a reference electric potential, and a sub-reference electrode, which is also provided with the reference electric potential. The sub-reference electrode is disposed in a mutually displaceable manner relative to the detection electrode, such that the sub-reference electrode and detection electrode are displaced relative to one another due to a pressure exerted by the detection object.

The sensor further includes a voltage application device, an electric current detector, a capacitance detector, and a detection unit. The voltage application device applies a detection voltage to form an electric field in a space defined with the reference electrode. The electric current detector detects an electric current in the detection electrode caused by the detection voltage from the voltage application device.

The capacitance detector detects a first capacitance and a second capacitance based on the detection voltage and the electric current detected by the electric current detector. The detection unit distinguishingly detects the detection object based on the first capacitance and the second capacitance. The first capacitance is provided between the detection electrode and the reference electrode, and the second capacitance is provided between the detection electrode and the sub-reference electrode.

According to such configuration, the mutually displacing movement between the detection electrode and the sub-reference electrode due to a pressure from the detection object causes a formation of an additional electric field between the detection electrode and the sub-reference electrode, which is an addition to the electric field between the detection electrode and the reference electrode. Therefore, the increase of capacitance is greater by an amount that is equal to the second capacitance, thereby enabling an accurate detection and identification of the detection object. In particular, the presence of a detection object is detected and a type of the detection object is also distinguishingly detected.

In another aspect of the present disclosure, a capacitance type sensor may include a first sensor part and a second sensor part. The first sensor part has a first detection electrode that faces a detection object and a first sub-reference electrode that is disposed on a far side of the first detection electrode relative to the detection object and is provided with the reference electric potential.

The second sensor part has a second detection electrode and a second sub-reference electrode. The second detection electrode is arranged to face the detection object, and is disposed separately from but is parallel with the first detection electrode. The second sub-reference electrode is disposed on a far side of the second detection electrode relative to the detection object and is also provided with the reference electric potential. The first sensor part and the second sensor part are disposed in a mutually displaceable manner, such that the first sensor part and the second sensor part displace relative to one another due to the pressure exerted from the detection object.

The voltage application device applies the detection voltage to form an electric field in a space defined by the first detection electrode and the second detection electrode. The electric current detector detects the electric current in the first detection electrode and the second detection electrode.

The capacitance detector detects a first capacitance and a second capacitance based on the detection voltage and the electric current detected by the electric current detector. The detection unit distinguishingly detects the detection object based on the first capacitance and the second capacitance.

The first capacitance is measured between the reference electrode and the first detection electrode and between the reference electrode the second detection electrode. The second capacitance is measured between the first detection electrode and the second sub-reference electrode and between the second detection electrode and the first sub-reference electrode.

According to such configuration, the mutually displacing movement between the detection electrode and the sub-reference electrode due to the pressure from the detection object causes a formation of an additional electric field between one of the detection electrodes and one of the sub-reference electrodes, which is in addition to the electric field between the detection electrode and the reference electrode. Therefore, the increase of capacitance is greater by an amount that is equal to the second capacitance, thereby enabling an accurate detection and identification of the detection object.

### BRIEF DESCRIPTION OF THE DRAWINGS

Other objects, features and advantages of the present disclosure will become more apparent from the following detailed description disposed with reference to the accompanying drawings, in which:

FIG. 1 is an illustration of a capacitance type sensor of the present disclosure;

FIG. 2 is a circuit diagram of the capacitance type sensor in the first embodiment;

FIG. 3 is a is a top view of a sensor body part of the first embodiment;

FIG. 4 is cross-sectional view of the sensor body part along a IV-IV line of FIG. 3;

FIG. 5 is an illustration of the sensor body part of the first embodiment in a case where the sensor body part is not displaced;

FIG. 6 is an illustration of the sensor body part of the first embodiment in a case where the sensor body part is displaced;

FIG. 7 is an illustration of the sensor body part of the first embodiment having a CRS disposed thereon;

FIG. 8 is an illustration of the sensor body part of the first embodiment having an adult seated thereon;

FIG. 9 is a graph comparing the capacitance detected by the capacitance type sensor of the present disclosure and by a conventional sensor;

FIG. 10 is an illustration of a capacitance type sensor in a second embodiment of the present disclosure;

FIG. 11 is a top view of the sensor body part in a third embodiment of the present disclosure;

FIG. 12 is a cross-sectional view of the sensor body part along a XII-XII line of FIG. 11;

FIG. 13 is an illustration of the sensor body part of the third embodiment in a case where the sensor body part is not displaced;

FIG. 14 is an illustration of the sensor body part of the third embodiment in a case where the sensor body part is displaced;

FIG. 15 is an illustration of the sensor body part of the third embodiment having a CRC disposed thereon;

FIG. 16 is an illustration of the sensor body part of the third embodiment having an adult seated thereon;

FIG. 17 is an illustration of a pressure distribution of the sensor body part having the adult seated thereon;

FIG. 18 is an illustration of a pressure distribution of the sensor body part having the CRS disposed thereon; and

FIG. 19 is an illustration of a modification of the sensor body part used in the second embodiment.

### DETAILED DESCRIPTION

The following description of the preferred embodiments will now be described with reference to the drawings. The drawings used in the description of the following embodiments are intended to depict a concept of the present disclosure, and do not reflect the dimensions of an actual product.

### First Embodiment

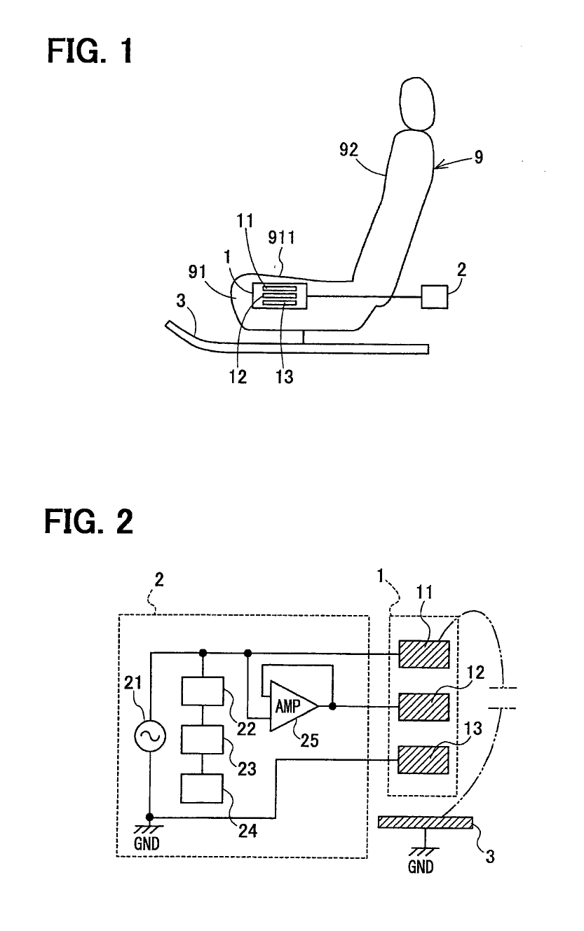

With reference to FIGS. 1 and 2, a capacitance type sensor in the first embodiment includes a sensor body part 1, an occupant detection ECU 2, and a vehicle body 3. The sensor body part 1 is a film like sensor mat, which is disposed in a seat part 91 of a seat 9 in a vehicle (e.g., in between cushions in the seat 9). The seat 9 has the seat part 91 with a seat surface 911 and a back part 92.

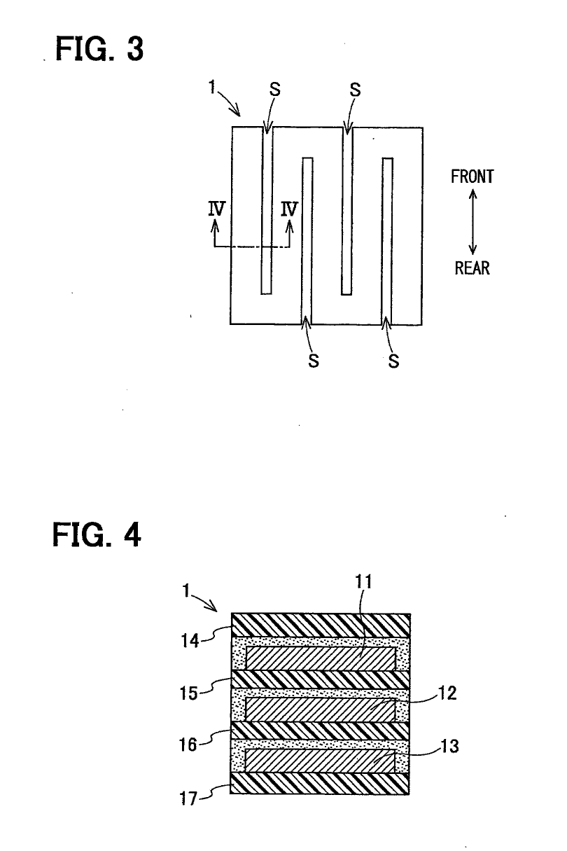

With reference to FIG. 3, the sensor body part 1 has at least one slit S that extends along an axis that is parallel with front-rear axis of the vehicle, and a surface plane of the sensor body part 1 may have a wave form. With reference to FIG. 4, which is a partial cross-sectional view of the sensor body part 1 along line IV-IV of FIG. 3, the sensor body part 1 includes a detection electrode 11, a guard electrode 12, a sub-reference electrode 13, and film members 14, 15, 16, 17, which are disposed in between the electrodes 11, 12, 13. The film members 14 to 17 are made of insulation material (e.g., PET), and are in the above-described order of 14, 15, 16, and 17 from a seat surface 911 side toward a vehicle body 3 side. An adhesive is disposed between the film members.

The detection electrode 11 is made of a flat board shape conductive material, and is disposed in an upper part of the sensor body unit 1 and parallel to the surface plane of the sensor body unit 1. The detection electrode 11 is bound by the film members 14, 15. The detection electrode 11 is arranged to be substantially parallel with a detection surface, such as the seat surface 911. Accordingly, when a detection object is within a detection range, the detection electrode 11 faces the detection object. In the present embodiment, the detection range of the detection object is the seat surface 911. The detection electrode 11 is connected to a voltage application part 21 and an electric current detector 22 to be mentioned later.

The guard electrode 12 has substantially the same configuration as the detection electrode 11, and is disposed below the detection electrode 11 with the film member 15 interposed therebetween. The guard electrode 12 is bound by the film members 15 and 16. The guard electrode 12 is connected to an op-amp 25 to be mentioned later.

The sub-reference electrode 13 has substantially the same configuration as the vehicle body 3, and is disposed below the guard electrode 12 with the film member 16 interposed therebetween. The sub-reference electrode 13 is bound by the film members 16, 17. The sub-reference electrode 13 is connected to a vehicle ground GND which has a reference electric potential/voltage.

The occupant detection ECU 2 is an electronic control unit, and, as shown in FIG. 2, includes the voltage application part 21, the electric current detector 22, a capacitance detection part 23, a detection unit 24, and the op-amp 25.

The voltage application part 21 is connected to the vehicle ground GND and to the detection electrode 11. The voltage application part 21 is an AC (i.e., alternating current) power supply, and applies an AC voltage (i.e., a detection voltage) to the detection electrode 11. In such manner, the detection electrode 11 forms an electric field in a gap space towards the vehicle body 3 that is connected to GND (i.e., may also be designated as a “detection-body gap space”).

The electric current detector 22 is an electric current sensor, and detects an electric current flowing in the detection electrode 11 by having a voltage application from the voltage application part 21.

The capacitance detection part 23 is connected to the electric current detector 22 and to the detection unit 24. The capacitance detection part 23 calculates the capacitance in the electric field that is formed by the detection electrode 11, based on the voltage that is applied by the voltage application part 21 and the electric current detected by the electric current detector 22. The capacitance is calculated based on an imaginary part of the impedance in the electric current path at a time of application of the voltage, and the imaginary part of the impedance is calculated based on a phase shift between the electric current and the voltage.

The detection unit 24 determines whether an occupant is sitting on the seat 9, and whether the occupant is an adult or a CRS, based on a detection result of the capacitance detection part 23 and a predetermined threshold.

The op-amp 25 is an operational amplifier, and has the voltage application part 21 connected to an input terminal, and has the guard electrode 12 connected to an output terminal. The op-amp 25 applies, to the guard electrode 12, the same voltage that is applied to the detection electrode 11. In such manner, the detection electrode 11 and the guard electrode 12 have the same electric potential.

The guard electrode 12 prevents a formation of an electric field between the detection electrode 11 and the vehicle body 3 or between the detection electrode 11 and the sub-reference electrode 13, which are on a lower side of the detection electrode 11 (i.e., an opposite side of the seat surface 911), by having the same electric potential as the detection electrode 11. In other words, the guard electrode 12 constrains the detection electrode 11 to form an electric field toward the seat surface 911.

The vehicle body 3 serves as a body of a vehicle, and also serves as an electrode, and has a reference electric potential, i.e., the vehicle ground GND.

The effects and advantages of the present embodiment are now illustrated.

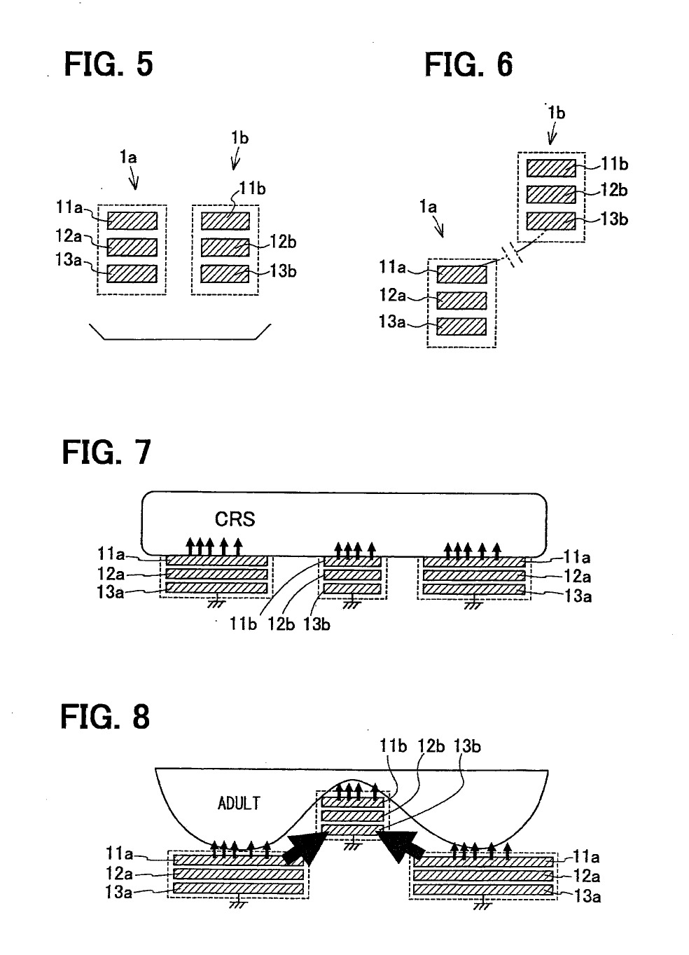

Since the sensor body part 1 has substantially parallel slits extending in the front-rear axis, the sensor body part 1 is divided into many sets (i.e., bundles) of electrodes respectively having the electrodes 11 to 13 (FIG. 3) and extending in the front-rear axis. Two sets of electrodes are shown in FIG. 5, in which the two sets of electrodes are arranged next to each other, and are designated as a first sensor part 1a and a second sensor part 1b.

The first sensor part 1a includes a first detection electrode 11a, a first guard electrode 12a, and a first sub-reference electrode 13a. The second sensor part 1b includes a second detection electrode 11b, a second guard electrode 12b, and a second sub-reference electrode 13b. Each of the first and second electrodes (11a and 11b, 12a and 12b, 13a and 13b) are connected with each other at their ends on one side. The detection electrode 11a, 11b are arranged above the guard 12a, 12b (i.e., on a seat surface 911 side of the guard 12a, 12b), and the guard electrodes 12a, 12b are arranged above the sub-reference electrodes 13a, 13b (i.e., on a seat surface 911 side of the sub-reference electrodes 13a, 13b).

When the sensor body unit 1 is not displaced (i.e., not deformed), the first sensor part 1a and the second sensor part 1b are arranged side by side, i.e., on the right and on the left. In other words, the first sensor part 1a and the second sensor part 1b are arranged with a gap interposed therebetween and are arranged in parallel. The arrangement of the first sensor part 1a and the second sensor part 1b may also be described, for example, as extending in parallel with the seat surface 911, or in parallel with a plane defined by the seat surface 911, or running in parallel with each other. In such a state, each of the first and second sensor parts 11a, 11b forms an electric field in a gap space between itself and the vehicle body 3.

When the sensor body unit 1 is partially displaced (FIG. 6), such that, for example, the first detection electrode 11a is pressed downward, the first detection electrode 11a forms an electric field in a gap space between itself and the second sub-reference electrode 13b, and forms an electric field in a gap space between itself and the vehicle body 3.

In other words, the detected capacitance is a total of the detection-body gap capacitance (i.e., a “first capacitance”) and the capacitance between the detection electrode 11 and the sub-reference electrode 13 (i.e., a detection-sub gap capacitance, or a “second capacitance”). Therefore, the capacitance in an occupant sitting state is increased from the capacitance in a no-sitting state, due to the deformation of the sensor body part 1.

The arrangement of the sensor body part 1 and a distinction between an adult and a CRS are described in detail. As shown in FIG. 7, when a CRS having a child sitting therein is disposed on the seat surface 911, a pressure from the CRS against the seat surface 911 is evenly distributed on the seat surface 911, which means that no partial displacement is caused for the sensor body part 1.

On the other hand, when an adult is seated on the seat surface 911, as shown in FIG. 8, pressure from a hip portion and a thigh portion is greater than a pressure from other contacting portions, causing a partial displacement, i.e., a partial downward depression, of the sensor body part 1. In such manner, the electric field is formed not only in the detection-body gap space but also in the detection-sub gap space, thereby yielding a greater total capacitance by the capacitance amount from the detection-sub gap space. That is, the amount of increase of the capacitance in the present embodiment has a greater value than the conventional structure.

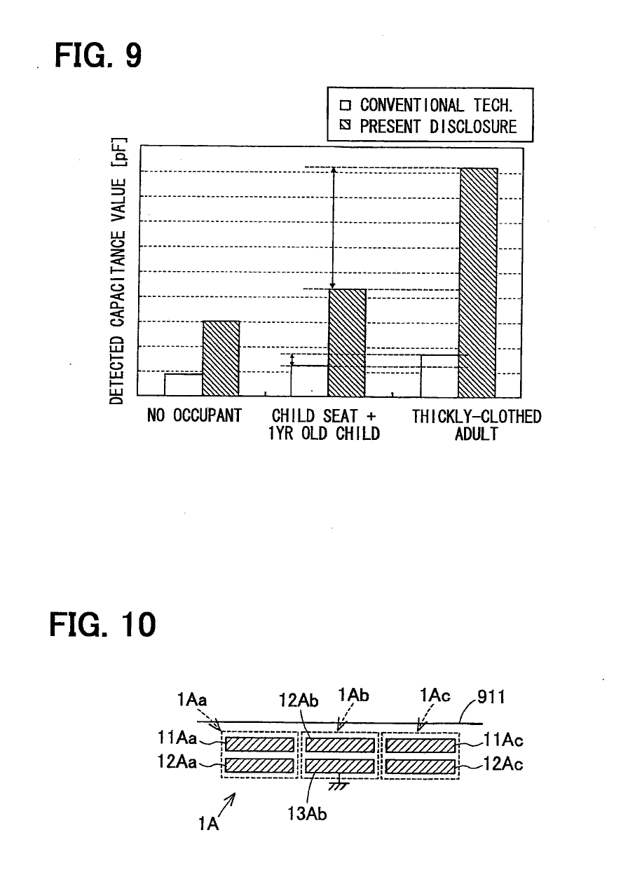

With reference to FIG. 9, a comparison between the capacitance generated using a conventional technique and the capacitance generated based on sensor body unit 1 of the present disclosure is provided for three different cases. The three cases provided are: no occupant, a CRS with a one year old child, and a thickly clothed adult. For all three cases the capacitance generated increased in comparison to the conventional technique.

Further, the difference between the capacitance detected for the CRS with the one year old child and the thickly-clothed adult significantly increased when compared to the difference using the conventional technique. Such a difference between the two cases is about ten times more than the difference using the conventional technique.

As described above, the distinction between an adult and a CRS is more accurately made regardless of whether an occupant is thickly-clothed or not, that is, regardless of the occupant conditions.

Further, as for the displacement under pressure, it may be caused only in the first sensor part 1a, or only in the second sensor part 1b, or may be caused in both of the sensor parts 1a, 1b. In other words, under pressure from the detection object, the first sensor part 1a and the second sensor part 1b may only have to be relatively displaceable/movable.

### Second Embodiment

The second embodiment of the capacitance type sensor is described with reference to FIG. 10. The difference of the second embodiment in comparison to the first embodiment is the arrangement of the electrode in the sensor body part. The following description is thus focused to such difference between the first and second embodiments. Further, the detection electrode, the guard electrode, and the sub-reference electrode respectively have the same function as the ones in the first embodiment.

The sensor body part 1A of the second embodiment is divided into bundles that extend along the front-rear axis (an axis perpendicular to the drawing) of the vehicle, and includes a first sensor part 1Aa, a second sensor part 1Ab, and a third sensor part 1Ac. The sensor body part 1A, when viewed from a top view. may have a wavy plane shape, like the first embodiment.

The first sensor part 1Aa includes a first detection electrode 11Aa and a first guard electrode 12Aa disposed below the first detection electrode 11Aa.

The second sensor part 1Ab includes a second guard electrode 12Ab and a second sub-reference electrode 13Ab disposed below of the second the guard electrode 12Ab.

The third sensor part 1Ac includes a third detection electrode 11Ac and a third guard electrode 12Ac disposed below the third detection electrode 11Ac.

The first detection electrode 11Aa, the second guard electrode 12Ab and the third detection electrode 11Ac are arranged substantially on the same plane. Likewise, the first guard electrode 12Aa, the second sub-reference electrode 13Ab and the third guard electrode 12Ac are arranged substantially on the same plane.

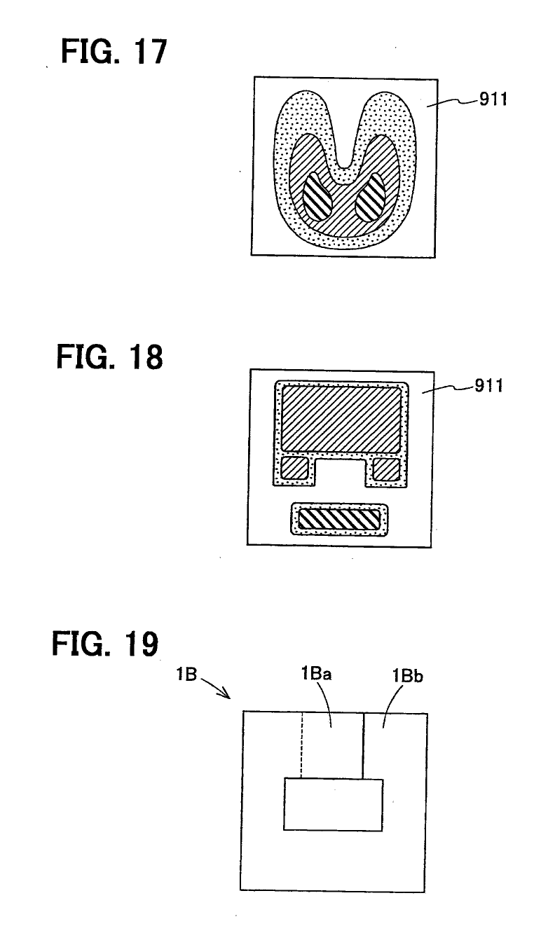

According to a sitting time pressure distribution illustrated in FIG. 17, the first sensor part 1Aa and the third sensor part 1Ac are positioned at a pressure-prone part of the seat surface 911 that receives pressure from an adult seated on the seat 9, and the second sensor part 1Ab is positioned at a pressure-less part which receives less or no pressure from the adult seated on the seat 9.

According to the second embodiment, when an adult is seated on the seat surface 911, a part of the sensor body part 1A is displaced, and the first sensor part 1Aa and the third sensor part 1Ac are pressed downward. In such manner, the first detection electrode 11Aa and the third detection electrode 11Ac respectively form an electric field toward the second sub-reference electrode 13Ab.

In other words, similar to the first embodiment, an electric field is formed not only in the detection-body gap space but also in the detection-sub gap space, thereby the capacitance increase is made greater. Thus, the second embodiment achieves the same effects and advantages as the first embodiment.

### Third Embodiment

The third embodiment of the capacitance type sensor differs from the first embodiment in the arrangement of the electrode in the sensor body part 1B. The following description is focused to such difference between the first and third embodiments. Further, the guard electrode and the sub-reference electrode respectively have the same function as the ones in the first embodiment.

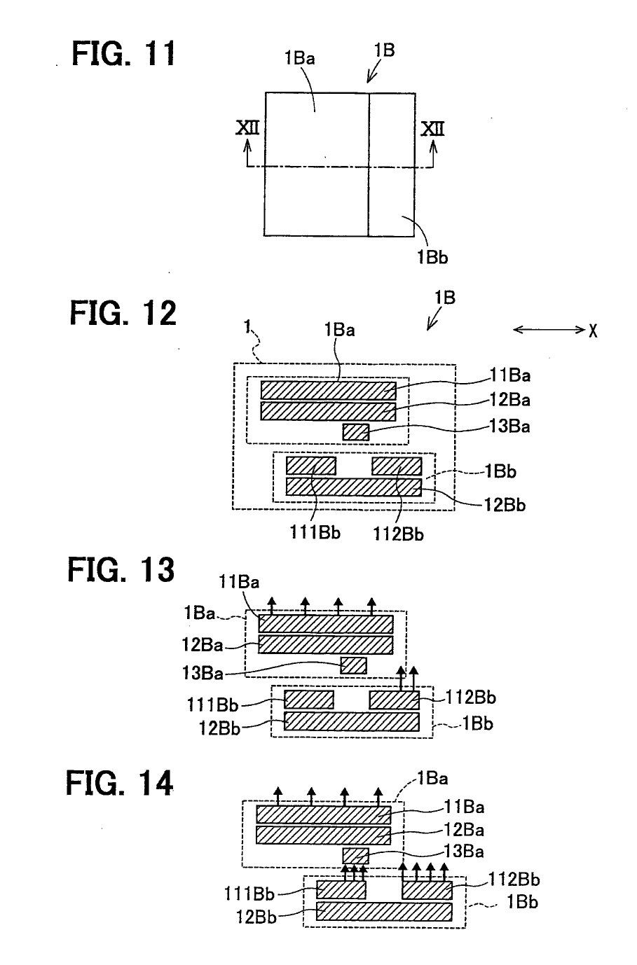

With reference to FIGS. 11 and 12, the sensor body part 1B of the third embodiment includes a first sensor part 1Ba and a second sensor part 1Bb that is disposed under the first sensor part 1Ba.

The first sensor part 1Ba includes a first detection electrode 11Ba, a first guard electrode 12Ba and a first sub-reference electrode 13Ba. The arrangement of the electrodes 11Ba, 12Ba, 13Ba in the first sensor part 1Ba is similar to the first embodiment. The width of the first sub-reference electrode 13Ba is smaller than the width of the first detection electrode 11Ba and the width of the first guard electrode 12Ba (i.e., width: the size along a X-axis, which is parallel to the right-left axis of the vehicle), and the first sub-reference electrode 13Ba is positioned to face a center of the second sensor part 1Bb.

The second sensor part 1Bb includes second detection electrodes 111Bb, 112Bb and a second guard electrode 12Bb. The second detection electrode 111Bb is arranged towards the left side of the second sensor part 1Bb along the X-axis of the second sensor part 1Bb. The second detection electrode 112Bb is arranged on the right side of the second sensor part 1Bb along the X-axis of the second sensor part 1Bb. The second detection electrodes 111Bb, 112Bb are arranged with a gap interposed therebetween at a center of the width of the second sensor part 1Bb.

The first sub-reference electrode 13Ba faces a no-electrode space, in which no detection electrode is provided, between the second detection electrodes 111Bb, 112Bb. In other words, the first sub-reference electrode 13Ba is positioned substantially above the gap (i.e., a no-electrode space) between the second detection electrode 111Bb and the second detection electrode 112Bb. The second guard electrode 12Bb is provided as one piece of metal, and is disposed under the second detection electrodes 111Bb, 112Bb.

The second sensor part 1Bb partially overlaps with the first sensor part 1Ba and has a shifted position toward the right side of the sensor body part 1B. Accordingly, a portion of the second detection electrode 112Bb is exposed from the first sensor part 1Ba (i.e., having no “ceiling” electrode above the electrode 112Bb), and thus allowing such portion to form an electric field through the occupant in the detection-body gap space.

When the sensor body part 1B is in a non-displaced state, as shown in FIG. 13, the first detection electrode 11Ba and a portion of the second detection electrode 112Bb form an electric field with the vehicle body 3.

On the other hand, when the sensor body part 1B is in a displaced state, as shown in FIG. 14, such that the first sensor part 1Ba and the second sensor part 1Bb are displaced from each other along the width of the sensor body part 1B (i.e., in a “width expanding manner” or in a separating manner) a larger part of the second detection electrode 112Bb is exposed from the ceiling electrode above, thereby leading to an increase of capacitance formed by the second detection electrode 112Bb in the detection-body gap space.

Further, in the displace state, a relative movement of the sub-reference electrode 13 causes a mutually-facing positioning of the second detection electrode 111Bb and the first sub-reference electrode 13Ba. In other words, such a relative movement causes an increase of an overlapping area between the second detection electrode 111Bb and the first sub-reference electrode 13Ba. Therefore, an electric field is formed between two electrodes, and the capacitance from such electric field in the detection-body gap space contributes to an increase of a total amount of capacitance. In such a case, even when such displacement/movement is not yet caused, the capacitance in the detection-body gap space is detectable.

According to the third embodiment described above, a capacitance difference between an adult case and a CRS case may be made greater than the difference in the first/second embodiments, thereby increasing the detection/distinction accuracy to a higher level.

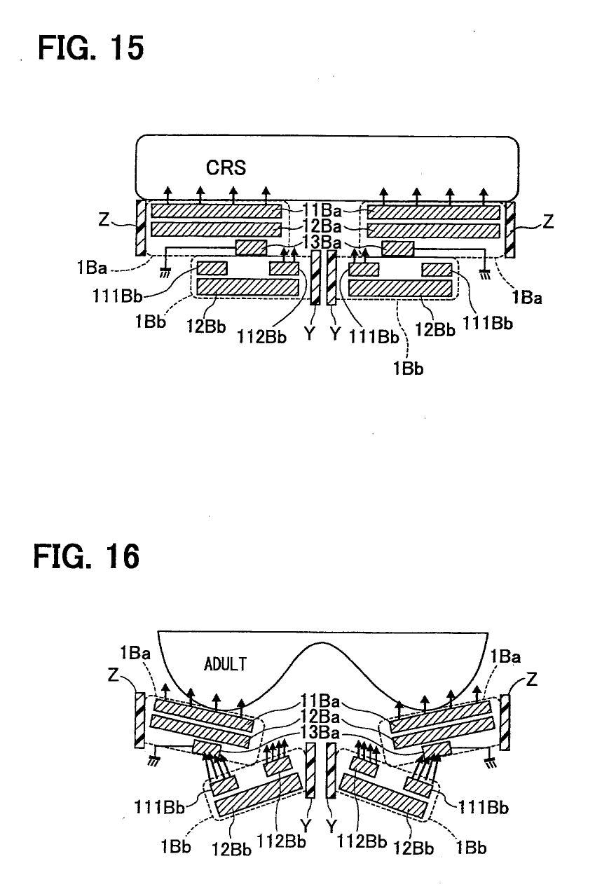

With reference to FIGS. 15 and 16, the sensor body part 1B has plural sensor parts, and the first sensor part 1Ba and the second sensor part 1Bb are arranged in symmetry, respectively as one set of sensors on the right and on the left. The following description is about one set of sensors on the left side, i.e., only for the left side set of sensors, for the brevity of the description.

The first sensor part 1Ba is fixed onto a left connection part Z of the seat part 91. The second sensor part 1Bb is arranged below the first sensor part 1Ba and is shifted towards the right. A right edge of the second sensor part 1Bb is fixed onto a fixed part Y, which is positioned at a center of the seat part 91. In such manner, one end of the sensor part 1Ba and one end of the sensor part 1Bb are respectively fixed onto the seat part 91. In addition, the left connection part Z may be a urethane portion of the seat part 91.

When a CRS is disposed on the seat surface 911 as shown in FIG. 15, the sensor body part 1 is hardly displaced, since a pressure from the CRS is evenly distributed across the sensor body part 1. In such a state, the capacitance in the detection-body gap space and the capacitance between the second detection electrode 111B and the sub-reference electrode 13 are respectively detected as described above.

On the other hand, when an adult sits on the seat surface 911 (FIG. 16), the contacting parts, such as a hip and the like, strongly press the sensor body part 1B, and the sensor body part 1 is displaced. More practically, the right-side end of the first sensor part 1Ba is pressed down, which presses down on the left-side end of the second sensor part 1Bb.

In such manner, a greater portion of the second detection electrode 112Bb is exposed from under the first detection electrode 11Ba (i.e., having a greater exposure area size through a cushion against the occupant). In addition, the first sub-reference electrode 13Ba and the second detection electrode 111Bb move such that they face one another. Therefore, an increase of the detected capacitance is caused.

<Modification>

The present disclosure may be modified in the following manner.

The sensor body part 1, 1A, 1B may be configured based on a pressure distribution of an occupant seated on the seat surface 911.

FIGS. 17 and 18 respectively show a conceptual diagram, in which a dotted portion has a higher pressure than a white portion, a thin slant line portion has a higher pressure than the dotted portion, a thick slant line portion has a higher pressure than the thin slant line portion (i.e., white<dot<thin slant line<thick slant line). FIG. 17 represents the pressure distribution of an adult seated on the seat surface 911, and FIG. 18 represents the pressure distribution of an CRS arranged on the seat surface 911. Accordingly, based on the pressure distribution, the sensor body part 1, as illustrated by FIGS. 8 and 16, may be arranged along the hip and/or the thigh position, so that a greater capacitance can be generated in a securer manner.

The detection unit 24 may be disposed in another ECU (e.g., in an airbag ECU) instead of in the occupant detection ECU 2.

Further, the sensor body part 1 may have an electrode (not illustrated) for detecting a liquid spill. A liquid spill detection electrode may be disposed along the detection electrode 11 substantially along the same plane as the detection electrode 11. In other words, the liquid spill detection electrode may be disposed next to the detection electrode 11 with a space interposed therebetween.

For the detection of an occupant, the liquid spill detection electrode is provided with the same voltage as the detection electrode 11. For the detection of a liquid spill, the liquid spill detection electrode is provided with the reference voltage, and a capacitance between the detection electrode 11 and the water spill detection electrode (i.e., a capacitance in a detection-spill gap space) is detected. Based on the capacitance in a “detection-spill gap space,” a liquid spill on the seat surface 911 is detected.

Further, in the sensor body part, the first sensor part 1Ba and the second sensor part 1Bb may simply be formed as separate parts, that is, as separate bodies/lumps, in a manner that allows separate displacement of each part. That is, the sensor body part 1 may have a railing shape, or one bundle/lump and the other bundle/lump (i.e., the first sensor part 1b and the second sensor part 1b facing each other in FIG. 5) may simply have separate bodies. More practically, one edge of the first sensor part 1b may simply be separated from an edge of the second sensor part 1b in FIG. 5.

When those bundles/lumps have separate bodies, each of the bundles/lumps is connected the occupant detection ECU 2, and the voltage application part 21 may apply the voltage to each of them, and the electric current detector 22 may detect an electric current in each of them.

The degree of freedom of the positioning of the parts may be increased by forming the bundles/lumps as separate bodies, and the production of the sensor body part may be made easier as well. For example, the sensor body part 1 in the first embodiment may have long board shape first and second sensor parts 1a, 1b.

In case the sensor body part is formed in one body (i.e., in a slit formation), production steps and man-hours may be reduced. In the third embodiment, if the sensor body part has one body (i.e., one-piece molding), the sensor body part may have a configuration of FIG. 19. In such configuration, two bundles/lumps are connected on one end.

Further, the guard electrode 12 is dispensable. However, having the guard electrode 12 provides a securer formation of the electric field through the detection object.

The above-described modification examples respectively have the same advantageous effects as the base embodiment that serves as a basis of such modification. Further, the drawing of the modification examples has a film member omitted therefrom.

Further, the present disclosure may be applicable to a touch/contact detection sensor of a touch panel device. For example, if we consider the press by a body of an adult in FIG. 8 and FIG. 16 as a press performed by a finger, the same effects and advantages are expected. According to the present disclosure, when a displaceable flexible touch screen (i.e., a contact surface) is pressed by a finger or the like, the touch screen and the sensor body part 1, 1A, 1B are displaced, and an increase of the capacitance is detected as described in the above embodiments. In such a case, the capacitance type sensor in the present disclosure is formed/disposed in a case (i.e., a body) having the screen. Such case/body or the seat part 91 may serve as a body part accommodating the sensor body part 1, 1A, 1B, and the touch screen and the seat surface 911 may serve as a contact surface that contacts the detection object.

Further, the present disclosure may have no contact surface. That is, the detection object may directly apply pressure against the sensor body part 1, 1A, 1B, the detection electrode 11, the first sensor part 1a, 1Aa, 1Ba, and/or the second sensor part 1b, 1Ab, 1Bb.

In other words, the pressure on the sensor body part 1, 1A, 1B by the detection object may be directly applied, or may be indirectly applied through a contact surface such as the seat surface 911, the screen or the like.

Although the present disclosure has been fully described in connection with the preferred embodiment thereof with reference to the accompanying drawings, the process is to be noted that various changes and modifications will become apparent to those skilled in the art, and such changes and modifications are to be understood as being within the scope of the present disclosure as defined by the appended claims.

What is claimed is:

1. A capacitance type sensor comprising:
a detection electrode arranged to face a detection object;
a reference electrode provided with a reference electric potential;
a sub-reference electrode provided with the reference electric potential and disposed in a mutually displaceable manner relative to the detection electrode, wherein the sub-reference electrode and the detection electrode are displaced relative to one another due to a pressure exerted from the detection object;
a voltage application device applying a detection voltage to form an electric field in a space defined with the reference electrode;
an electric current detector detecting an electric current in the detection electrode caused by the detection voltage from the voltage application device;
a capacitance detector detecting, based on the detection voltage and the electric current detected by the electric current detector, a first capacitance between the detection electrode and the reference electrode and a second capacitance between the detection electrode and the sub-reference electrode; and
a detection unit distinguishingly detecting the detection object based on the first capacitance and the second capacitance.

2. The capacitance type sensor of claim 1 further comprising:
a guard electrode having substantially same voltage as the detection voltage applied thereto, wherein
the guard electrode is positioned between the sub-reference electrode and the detection object.

3. The capacitance type sensor of claim 1 further comprising:
a guard electrode having substantially same voltage as the detection voltage applied thereto, wherein
the guard electrode is positioned between the detection electrode and the sub-reference electrode.

4. The capacitance type sensor of claim 1, wherein
the detection electrode and the sub-reference electrode are disposed inside of a seat part of a seat of a vehicle,
the reference electrode is a vehicle body, and
the detection unit distinguishingly detects an occupant of the vehicle based on the first capacitance and the second capacitance.

5. The capacitance type sensor of claim 4, wherein the detection electrode and the sub-reference electrode are arranged based on a pressure position exerted by the occupant seated on the seat.

6. A capacitance type sensor comprising:
a reference electrode provided with a reference electric potential;
a first sensor part having a first detection electrode facing a detection object and having a first sub-reference electrode disposed on a far side of the first detection electrode relative to the detection object with the reference electric potential provided therewith;
a second sensor part having a second detection electrode facing the detection object, disposed separately from the first detection electrode, and being parallel with the first detection electrode, and having a second sub-reference electrode disposed on a far side of the second detection electrode relative to the detection object with the reference electric potential provided therewith;
a voltage application device applying a detection voltage to form an electric field in a space define by the first detection electrode and the second detection electrode;
an electric current detector detecting an electric current in the first detection electrode and the second detection electrode, the electric current being caused by the detection voltage;
a capacitance detector detecting a first capacitance and a second capacitance based on the detection voltage and the electric current detected by the electric current detector; and
a detection unit distinguishingly detecting the detection object based on the first capacitance and the second capacitance, wherein
the first sensor part and the second sensor part are disposed in a mutually displaceable manner, such that the first sensor part and the second sensor part displace due to pressure exerted from the detection object,
the first capacitance is between the reference electrode and the first detection electrode and between the reference electrode the second detection electrode, and
the second capacitance is between the first detection electrode and the second sub-reference electrode and between the second detection electrode and the first sub-reference electrode.

7. The capacitance type sensor of claim 6, wherein the first sensor part and the second sensor part are provided as separate bodies, and the electric current detector detects the electric current in each of the first sensor part and the second sensor part.

8. The capacitance type sensor of claim 6, wherein
the first sensor part has a first guard electrode disposed between the first detection electrode and the first sub-reference electrode, and the second sensor part has a second guard electrode disposed between the second detection electrode and the second sub-reference electrode.

9. The capacitance type sensor of claim 6, wherein
the first sensor part and the second sensor part are disposed inside of a seat part of a seat of a vehicle,
the reference electrode is a vehicle body, and
the detection unit distinguishingly detects an occupant of the vehicle based on the first capacitance and the second capacitance.

10. The capacitance type sensor of claim 9, wherein the first sensor part and the second sensor part are arranged based on a pressure position exerted by the occupant seated on the seat.
